(19) United States
(12) Patent Application Publication
(10) Pub. No.: US 2025/0203948 A1
(43) Pub. Date: Jun. 19, 2025

(54) SEMICONDUCTOR STRUCTURES AND MANUFACTURING METHODS THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/735,591

(22) Filed: Jun. 6, 2024

(30) Foreign Application Priority Data
Dec. 19, 2023 (CN) 202311754925.0

(51) Int. Cl. H01L 29/786; H01L 29/06; H01L 29/20; H01L 29/417; H01L 29/423; H01L 29/45; H01L 29/66; H01L 29/775

(52) U.S. Cl. CPC H10D 30/6757; H10D 30/014; H10D 30/43; H10D 30/6735; H10D 30/6737; H10D 30/675; H10D 62/121; H10D 62/8503; H10D 30/6729

(57) ABSTRACT

The present disclosure provides a semiconductor structure, including: a substrate; a channel structure on the substrate, a first N-type heavily doped layer and a second N-type heavily doped layer. The channel structure includes a first intermediate layer, a channel layer, and a second intermediate layer that are sequentially arranged on the substrate, where a width of a cross-section of the channel layer is smaller than a width of a cross-section of the first intermediate layer, and the second intermediate layer covers sidewalls of the channel layer and a surface of the channel layer far from the first intermediate layer. The first N-type heavily doped layer is between the substrate and the channel structure, and the second N-type heavily doped layer is on a side of the channel structure far from the substrate.

### CROSS REFERENCE TO RELATED APPLICATIONS

This application claims priority to Chinese Patent Application No. 2023117549250, filed on Dec. 19, 2023, the entire content of which is incorporated herein by reference.

### TECHNICAL FIELD

The present disclosure relates to the technical field of semiconductor devices, in particular to semiconductor structures and manufacturing methods therefor.

### BACKGROUND

Gallium nitride (GaN), as a representative of the third generation of wide band gap semiconductor, is attracting widespread attention. Properties of GaN mainly include high electron mobility and high two-dimensional electron gas (2DEG) concentration. In addition, GaN material has stable chemical properties, high temperature resistance and corrosion resistance, and has inherent advantages in high-frequency, high-power, and radiation-resistant applications.

In a planar device, current laterally flows in a quantum well formed by a heterojunction structure. Under a reversebias, a distribution of electric field in a device is usually uneven. Generally, severe electric field concentration occurs at an edge of the gate electrode or the drain electrode, and the electric field there increases rapidly with an increase of reverse voltage. When a critical breakdown field strength is reached, the device is broken down.

A high breakdown voltage means that the device operates in a larger voltage range, can achieve higher power density, and has higher reliability. Therefore, how to improve the gate control capability and breakdown voltage of devices is a key concern for electronic device researchers.

### SUMMARY

In order to solve the above-mentioned technical problems, the present disclosure is proposed. Embodiments of the present disclosure provide a semiconductor structure including:

a substrate;

a channel structure on the substrate, where the channel structure includes a first intermediate layer, a channel layer, and a second intermediate layer that are arranged on the substrate, where a width of a cross-section of the channel layer is smaller than a width of a cross-section of the first intermediate layer, and the second intermediate layer covers sidewalls of the channel layer and a surface of the channel layer far from the first intermediate layer, where the channel structure includes a gate region, and a source region and a drain region at both sides of the gate region;

a first N-type heavily doped layer and a second N-type heavily doped layer, where the first N-type heavily doped layer is between the substrate and the channel structure, and the second N-type heavily doped layer is on a side of the channel structure far from the substrate, and projection of the first N-type heavily doped layer on the channel structure and projection of the second N-type heavily doped layer on the channel structure are located within the gate region; and

a gate electrode within the gate region, where the gate electrode covers sidewalls of the first N-type heavily doped layer, the channel structure, and the second N-type heavily doped layer.

In some embodiments, the gate electrode is in ohmic contact with the first N-type heavily doped layer and the second N-type heavily doped layer.

In some embodiments, the semiconductor structure includes: a plurality of the channel structures that are stacked on the substrate; and

In some embodiments, a third N-type heavily doped layer between adjacent channel structures of the plurality of channel structures, and projection of the third N-type heavily doped layer on the channel structure is located within the gate region.

In some embodiments, the plurality of channel structures share the gate electrode, the gate electrode covers sidewalls of the third N-type heavily doped layer, and the gate electrode is in ohmic contact with the third N-type heavily doped layer.

In some embodiments, the channel layer is a nanowire structure or a nanosheet structure.

In some embodiments, a material of the channel structure includes a group-III nitride material.

In some embodiments, materials of the first intermediate layer and the second intermediate layer includes AlN; and

a material of the channel layer includes GaN, AlGaN, InGaN, or AlInGaN.

In some embodiments, the channel layer is an N-type lightly doped layer, and doping concentration of N-type ions for the channel layer is less than 1E18.

In some embodiments, a source electrode and a drain electrode, that are respectively at the source region and the drain region, where the source electrode and the drain electrode both wrap around the channel layer.

For the second aspect, the present disclosure further provides a manufacturing method for a semiconductor structure, including:

providing a substrate;

sequentially manufacturing a first N-type heavily doped layer, a channel structure, and a second N-type heavily doped layer on the substrate, where manufacturing the channel structure includes sequentially manufacturing a first intermediate layer, a channel layer, and a second intermediate layer on the first N-type heavily doped layer, where a width of a cross-section of the channel layer is smaller than a width of a cross-section of the first intermediate layer, and the second intermediate layer covers sidewalls of the channel layer and a surface of the channel layer far from the first intermediate layer;

the channel structure includes a gate region, and a source region and a drain region at both sides of the gate region;

removing parts of the first N-type heavily doped layer whose projection on the channel structure is within the source region and the drain region, and parts of the second N-type heavily doped layer whose projection on the channel structure is within the source region and the drain region;

manufacturing a gate electrode within the gate region, where the gate electrode covers sidewalls of the first N-type heavily doped layer, the channel structure, and the second N-type heavily doped layer.

In some embodiments, manufacturing the channel structure includes:

sequentially manufacturing the first intermediate layer and the channel layer on the first N-type heavily doped layer;

patterning the channel layer, to enable the width of the cross-section of the channel layer to be smaller than the width of the cross-section of the first intermediate layer; and

manufacturing the second intermediate layer on the first intermediate layer and the channel layer, where the second intermediate layer covers the sidewalls of the channel layer and the surface of the channel layer far from the first intermediate layer.

In some embodiments, patterning the channel layer includes:

patterning the channel layer to form a nanowire structure or a nanosheet structure.

In some embodiments, after removing parts of the first N-type heavily doped layer whose projection on the channel structure is within the source region and the drain region, and parts of the second N-type heavily doped layer whose projection on the channel structure is within the source region and the drain region, the manufacturing method further includes:

removing parts of the first intermediate layer that are located within the source region and the drain region, and parts of the second intermediate layer that are located within the source region and the drain region.

In some embodiments, after removing the parts of the first intermediate layer that are located within the source region and the drain region, and the parts of the second intermediate layer that are located within the source region and the drain region, the manufacturing method further includes:

respectively manufacturing a source electrode and a drain electrode at the source region and the drain region, where the source electrode and the drain electrode both wrap around the channel layer.

In some embodiments, the gate electrode is in ohmic contact with the first N-type heavily doped layer and the second N-type heavily doped layer.

In some embodiments, manufacturing the channel structure includes: manufacturing a plurality of the channel structures that are stacked on the substrate; and

the method further includes: manufacturing a third N-type heavily doped layer between adjacent channel structures in the plurality of channel structures, and the gate electrode is connected to the third N-type heavily doped layer, and the gate electrode is in ohmic contact with the third N-type heavily doped layer.

In some embodiments, removing the parts of the first N-type heavily doped layer whose projection on the channel structure is within the source region and the drain region, and the parts of the second N-type heavily doped layer whose projection on the channel structure is within the source region and the drain region includes:

removing the parts of the first N-type heavily doped layer whose projection on the channel structure is within the source region and the drain region, the parts of the second N-type heavily doped layer whose projection on the channel structure is within the source region and the drain region, and parts of the third N-type heavily doped layer whose projection on the channel structure is within the source region and the drain region.

In some embodiments, after manufacturing the channel layer, the manufacturing method further includes:

performing N-type doping on the channel layer, where doping concentration of N-type ions is less than 1E18.

### BRIEF DESCRIPTION OF DRAWINGS

By providing a more detailed description of the embodiments of the present disclosure in conjunction with the accompanying drawings, the aforementioned and other objects, features, and advantages of the present disclosure will become clearer. The accompanying drawings are used to provide a further understanding of the embodiments of the present disclosure and form a part of the specification. The accompanying drawings are used together with the embodiments of the present disclosure to explain the present disclosure and do not constitute any limitation of the present disclosure. In the accompanying drawings, the same reference number usually represents the same component or step.

FIG. 1 is a schematic diagram of a semiconductor structure provided in Embodiment 1 of the present disclosure.

FIG. 2 is a schematic cross-sectional diagram of a semiconductor structure provided in Embodiment 1 of the present disclosure.

FIG. 3 is a schematic diagram of a semiconductor structure provided in Embodiment 2 of the present disclosure.

FIG. 4 is a schematic cross-sectional diagram of a semiconductor structure provided in Embodiment 2 of the present disclosure.

FIGS. 5 to 10 are schematic diagrams of a flow for manufacturing a semiconductor structure provided in Embodiment 3 of the present disclosure.

FIGS. 11 to 12 are schematic diagrams of a partial flow for manufacturing a semiconductor structure provided in Embodiment 4 of the present disclosure.

### DETAILED DESCRIPTION

The technical solutions in the embodiments of the present disclosure are clearly described below with reference to the accompanying drawings in the embodiments of the present disclosure. The embodiments described are merely some embodiments of the present disclosure, and not all embodiments. Other embodiments achieved by those of ordinary skill in the art based on the embodiments in the present disclosure without paying creative work shall all fall within the scope of protection of the present disclosure.

### Embodiment 1

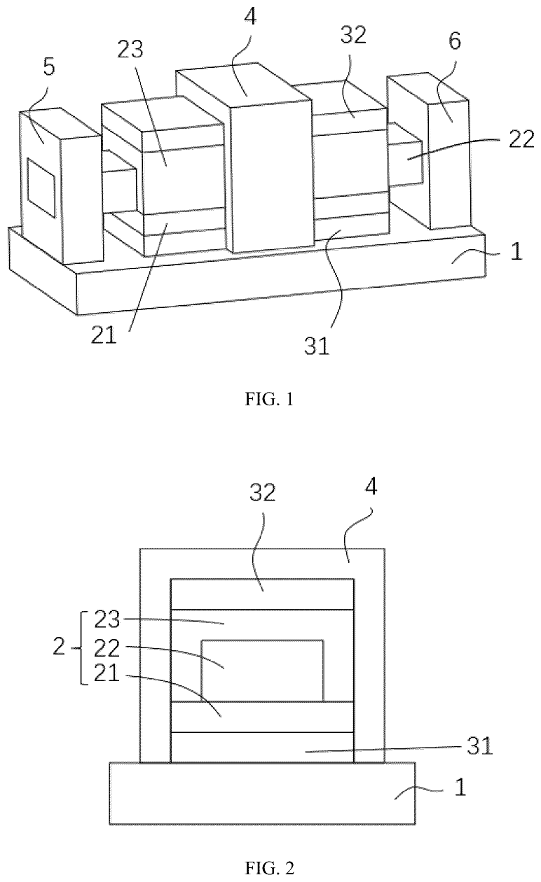

Embodiment 1 of the present disclosure provides a semiconductor structure. FIG. 1 is a schematic diagram of a semiconductor structure provided in Embodiment 1 of the present disclosure. As shown in FIG. 1, the semiconductor structure includes: a substrate 1, a channel structure 2 on the substrate 1, a first N-type heavily doped layer 31, second N-type heavily doped layer 32 and a gate electrode 4. The channel structure 2 includes a first intermediate layer 21, a channel layer 22, and a second intermediate layer 23 that are sequentially arranged on the substrate 1. The width of the cross-section of the channel layer 22 is smaller than the width of the cross-section of the first intermediate layer 21, where the cross-section is perpendicular to a channel direction. The second intermediate layer 23 covers the sidewalls of the channel layer 22 and the surface of the channel layer 22 far from the first intermediate layer 21, and the second intermediate layer 23 covers the surface of the first intermediate layer 21 that is exposed by the channel layer 22 and far from the substrate 1. The channel structure 2 includes a gate region, and a source region and a drain region located at both sides of the gate region. The first N-type heavily doped layer 31 is located between the substrate 1 and the channel structure 2. The second N-type heavily doped layer 32 is located on the side of channel structure 2 far from the substrate 1. The projections of the first N-type heavily doped layer 31 and the second N-type heavily doped layer 32 on channel structure 2 are located in the gate region. The gate electrode 4 is located within the gate region, and is connected to the first N-type heavily doped layer 31 and the second N-type heavily doped layer 32, i.e. The gate electrode 4 covers the sidewalls of channel structure 2, the sidewalls of the first N-type heavily doped layer 31, the sidewalls of the second N-type heavily doped layer 32, and the surface of the second N-type heavily doped layer 32 far from the substrate 1. In some embodiments, the gate electrode 4 may not cover the top of the second N-type heavily doped layer 32. Alternatively, the semiconductor structure can omit the second N-type heavily doped layer 32, and the gate electrode 4 directly covers the side of the second intermediate layer 23 far from the substrate 1.

Further referring to FIG. 2, FIG. 2 is a schematic cross-sectional diagram of a gate region of a semiconductor structure provided in Embodiment 1 of the present disclosure. In the semiconductor structure provided in the present disclosure, a gate structure is formed by a gate electrode 4 connecting the first N-type heavily doped layer 31 and the second N-type heavily doped layer 32, and the gate structure wraps around the sidewalls of the channel structure 2, thereby increasing the gate control area, making the electric field distribution more uniform, greatly improving the control ability of the gate 4 over the channel layer 22, effectively improving the breakdown voltage, reducing the leakage in the gate area, improving the dynamic characteristics, and improving the efficiency and linearity of the semiconductor structure. Besides, in the semiconductor structure provided in the present disclosure, the first intermediate layer 21, the channel layer 22, and the second intermediate layer 23 are sequentially formed on the first N-type heavily doped layer 31 to ensure the crystal quality of the channel layer 22 and device performance. Furthermore, the first N-type heavily doped layer 31 and the second N-type heavily doped layer 32 replace a metal material as part of the gate structure, and the channel structure 2 can be directly formed on the first N-type heavily doped layer 31. Therefore, the semiconductor structure provided by the present disclosure greatly reduces the difficulty of manufacturing the gate structure wrapping around the sidewalls of the channel layer 22, effectively reducing production costs.

As shown in FIG. 1, the semiconductor structure further includes a source electrode 5 located in the source region and a drain electrode 6 located in the drain region. The first N-type heavily doped layer 31, the first intermediate layer 21, the second intermediate layer 23, and the second N-type heavily doped layer 32 that are located in the source and drain regions at both sides of the channel structure 2 can be removed to expose the channel layer 22 located in the source and drain regions. The source electrode 5 and the drain electrode 6 surrounding the exposed channel layer 22 can be formed.

A material of substrate 1 can include Si, SiC, sapphire, or SOI (Silicon On Insulator), etc., which is not limited in the present disclosure.

The channel structure 2 includes a first intermediate layer 21, a channel layer 22, and a second intermediate layer 23 that are sequentially arranged on the first N-type heavily doped layer 31. The first intermediate layer 21 and the second intermediate layer 23 can be dielectric material layers, and the channel layer 22 can be a semiconductor material, such that the channel structure can form a channel during working, allowing carriers to communicate between the source electrode 5 and the drain electrode 6 through the channel, achieving conduction of the channel structure 2. A material of the channel structure includes a group-III nitride material. In some embodiments, the materials of the first intermediate layer 21 and the second intermediate layer 23 may include AlN, and the material of the channel layer 22 may include GaN, AlGaN, InGaN, or AlInGaN. The present disclosure does not limit the materials of the channel structure. In the semiconductor structure provided in this embodiment, the first intermediate layer 21 and the second intermediate layer 23 in the channel structure 2 are connected and wrap around the channel layer 22. The first intermediate layer 21 and the second intermediate layer 23 serve as a gate dielectric layer, which eliminates the need for additional gate dielectric layers, simplifies the manufacturing process of the semiconductor structure, improves manufacturing efficiency, and effectively reduces production costs.

The materials of the first N-type heavily doped layer 31 and the second N-type heavily doped layer 32 are group-III nitride materials. In some embodiments, the materials of the first N-type heavily doped layer 31 and the second N-type heavily doped layer 32 include GaN materials heavily doped with Si. In some embodiments, the doping concentration of the first N-type heavily doped layer 31 is greater than 1E18, and the doping concentration of the second N-type heavily doped layer 32 is greater than 1E18, which is not limited by the present disclosure. The gate electrode 4, the source electrode 5, and the drain electrode 6 are usually metal materials, such as nickel, nickel manganese alloy, etc., which is not limited in the present disclosure. In some embodiments, the gate electrode 4 forms ohmic contact with the first N-type heavily doped layer 31 and the second N-type heavily doped layer 32 to reduce ohmic contact resistance and improve gate control capability.

The heavily doping of the first N-type heavily doped layer 31 and the second N-type heavily doped layer 32 can be achieved through in-situ doping or implantation of N-type ions (such as Si ions), and the doping concentration can be greater than or equal to 1E18. The present disclosure does not limit the implementation method and doping concentration of heavily doping.

The channel layer 22 can be an N-type lightly doped layer. Similarly, the N-type lightly doped layer can be achieved by in-situ doping or implantation of N-type ions (such as Si ions) to improve electron transfer rate. The doping concentration of N-type ions can be less than 1E18, which is not limited in the present disclosure.

The first N-type heavily doped layer 31 and the second N-type heavily doped layer 32 conduct and combine with the gate electrode 4 to form a gate structure. The gate structure forms a fully enclosing structure for the channel structure 2, which controls the conduction and disconnection of the channel structure 2 through the voltage applied to the gate electrode 4. The projections of the first N-type heavily doped layer 31 and the second N-type heavily doped layer 32 on the channel structure 2 are located within the gate region. The first N-type heavily doped layer 31 and the second N-type heavily doped layer 32 conduct with gate electrode 4 to control the conduction and disconnection of channel structure 2 through the voltage applied to gate electrode 4. Therefore, the first N-type heavily doped layer 31 and the second N-type heavily doped layer 32 serve as part of the gate structure, and the first N-type heavily doped layer 31 and the second N-type heavily doped layer 32 combine with gate electrode 4 to form a gate structure to control the conduction and closure of channel structure 2.

In some embodiments, the channel layer 22 is a nanowire structure or a nanosheet structure.

In some embodiments, the semiconductor structure may further include a nucleation layer and/or buffer layer between the substrate 1 and the first N-type heavily doped layer 31. A material of the nucleation layer can include, for example, AlN, AlGaN, etc., and a material of the buffer layer can include at least one of AlN, GaN, AlGaN or AlInGaN. The nucleation layer can alleviate the lattice mismatch and thermal mismatch between the epitaxial grown semiconductor layer and the substrate, while the buffer layer can reduce the dislocation density and defect density of the epitaxial grown semiconductor layer, which can improve crystal quality.

### Embodiment 2

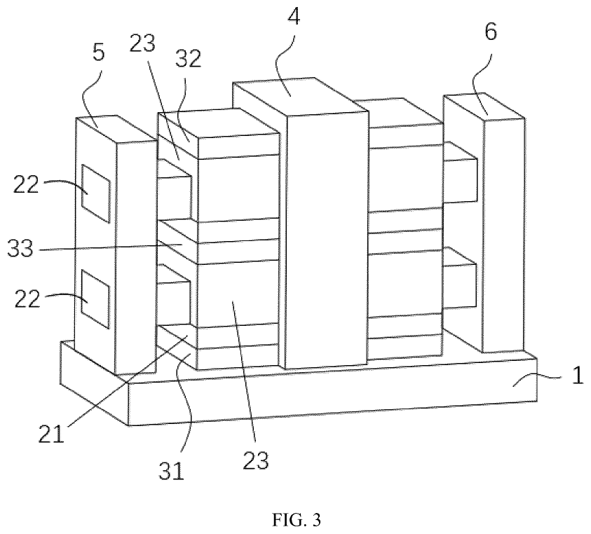

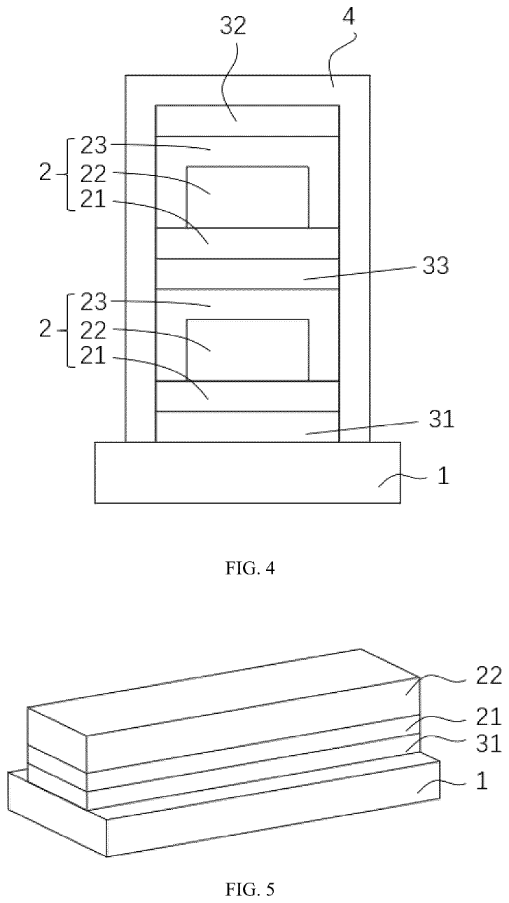

The content of Embodiment 2 is roughly the same as that of Embodiment 1, with the only difference being that, as shown in FIGS. 3 and 4, FIG. 3 is a schematic diagram of a semiconductor structure provided in Embodiment 2 of the present disclosure, and FIG. 4 is a schematic cross-sectional diagram of a gate region of a semiconductor structure provided in Embodiment 2 of the present disclosure. The semiconductor structure provided in Embodiment 2 includes a plurality of the channel structures 2, which are stacked on the substrate 1. The number of the channel structures 2 can be 2 or more, which is not limited in the present disclosure.

The plurality of channel structures 2 that are stacked can save space occupied by the structure, facilitate the manufacturing of smaller devices, improve the channel electron transfer efficiency of the semiconductor structure, and enhance device linearity and stability.

In some embodiments, the semiconductor structure further includes a third N-type heavily doped layer 33 between two adjacent channel structures 2 in the plurality of channel structures 2 (i.e., above the second intermediate layer 23 of the lower channel structure 2 and below the first intermediate layer 21 of the upper channel structure 2), and the projection of the third N-type heavily doped layer 33 on the channel structure 2 is located within the gate region.

In this embodiment, the plurality of channel structures 2 share a gate electrode 4. The gate electrode 4 is connected to the third N-type heavily doped layer 33, and the gate electrode 4 is in Ohmic contact with the third N-type heavily doped layer 33. The first N-type heavily doped layers 31, the second N-type heavily doped layers 32, and the third N-type heavily doped layers 33 serve as part of the gate structure. The first N-type heavily doped layers 31, the second N-type heavily doped layers 32, and the third N-type heavily doped layers 33 are connected to the gate electrode 4 to form a gate structure that surrounds each channel structure in the plurality of channel structures, which forms a fully enclosing structure for each channel structure 2, and controls the conduction and disconnection of each channel structure 2 by voltage applied to the gate electrode 4.

The material of the third N-type heavily doped layer 33 can be the same as that of the first N-type heavily doped layer 31 and the second N-type heavily doped layer 32.

In some embodiments, the plurality of channel structures share a gate electrode, a source electrode, and a drain electrode.

In the semiconductor structure provided in the embodiments, a gate structure is formed by a gate electrode 4 connecting the first N-type heavily doped layer 31, the second N-type heavily doped layer 32 and the third N-type heavily doped layers 33, and the gate structure wraps around the sidewalls of the channel structure 2, thereby increasing the gate control area, making the electric field distribution of each channel structure 2 more uniform, greatly improving the control ability of the gate 4 over each channel layer 22, effectively improving the breakdown voltage, reducing the leakage in the gate area, improving the dynamic characteristics, and improving the efficiency and linearity of the semiconductor structure. Besides, in the semiconductor structure provided in the present disclosure, the first intermediate layer 21, the channel layer 22, and the second intermediate layer 23 are sequentially formed on the first N-type heavily doped layer 31 to ensure the crystal quality of the channel layer 22 and device performance. Furthermore, the first N-type heavily doped layer 31 and the second N-type heavily doped layer 32 replace a metal material as part of the gate structure, and the channel structure 2 can be directly formed on the first N-type heavily doped layer 31. Therefore, the semiconductor structure provided by the present disclosure greatly reduces the difficulty of manufacturing the gate structure wrapping around the sidewalls of the channel layer 22, effectively reducing production costs.

### Embodiment 3

Embodiment 3 provides a manufacturing method for the semiconductor structure provided in Embodiment 1, as shown in FIGS. 5 to 10. FIGS. 5 to 10 are schematic diagrams of a flow for manufacturing a semiconductor structure provided in Embodiment 3 of the present disclosure. The manufacturing method includes: providing a substrate 1; sequentially manufacturing a first N-type heavily doped layer 31, a channel structure 2, and a second N-type heavily doped layer 32 on the substrate 1. Manufacturing the channel structure 2 includes sequentially manufacturing the first intermediate layer 21, the channel layer 22, and the second intermediate layer 23 on the first N-type heavily doped layer 31. The width of the cross-section of the channel layer 22 is smaller than the width of the cross-section of the first intermediate layer 21, where the cross-section is perpendicular to a channel direction. The second intermediate layer 23 covers the sidewalls of the channel layer 22 and the surface of the channel layer 22 far from the first intermediate layer 21, and the second intermediate layer 23 covers the surface of the first intermediate layer 21 that is exposed by the channel layer 22 and far from the substrate 1. The channel structure 2 includes a gate region and source and drain regions located at both sides of the gate region. The method further includes: removing parts of the first N-type heavily doped layer 31 whose projection on the channel structure 2 is within the source region and the drain region, and parts of the second N-type heavily doped layer 32 whose projection on the channel structure 2 is within the source region and the drain region; and manufacturing a gate electrode 4 within the gate region, and the gate electrode 4 covers the sidewalls of the first N-type heavily doped layer 31, the channel structure 2, and the second N-type heavily doped layer 32. The gate electrode 4 is connected to the first N-type heavily doped layer 31 and the second N-type heavily doped layer 32. In some embodiments, the gate electrode 4 can also cover the surface of the second N-type heavily doped layer 32 on one side far from the substrate 1.

As shown in FIG. 5, the substrate 1 is provided, and the first N-type heavily doped layer 31, the first intermediate layer 21, and the channel layer 22 are sequentially manufactured on the substrate 1. The manufacturing of the first N-type heavily doped layer 31, the first intermediate layer 21, and the channel layer 22 may include: atomic layer deposition (ALD), chemical vapor deposition (CVD), molecular beam epitaxial growth (MBE), plasma enhanced chemical vapor deposition (PECVD), low pressure chemical vapor deposition (LPCVD), metal organic chemical vapor deposition (MOCVD), or any combination thereof, which is not limited in the present disclosure. In some embodiments, when the channel layer 22 is manufactured, N-type doping can be applied to the channel layer 22. The doping concentration of N-type ions is less than 1E18, and the doping method can be in-situ doping or ion implantation, which is not limited in the present disclosure. The materials of the first N-type heavily doped layer 31 and the second N-type heavily doped layer 32 can be GaN materials heavily doped with Si. In some embodiments, the doping concentration of the first N-type heavily doped layer 31 is greater than 1E18, and the doping concentration of the second N-type heavily doped layer 32 is greater than 1E18, which is not limited by the present disclosure.

Referring to FIG. 6, the channel layer 22 is patterned to form a nanowire or nanosheet structure.

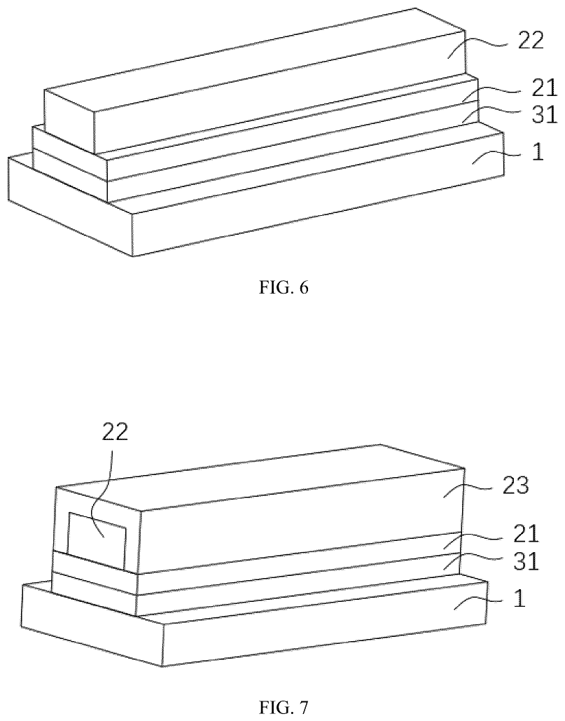

Referring to FIG. 7, the second intermediate layer 23 is simultaneously manufactured on the first intermediate layer 21 and the channel layer 22 to form the channel structure 2. The second intermediate layer 23 covers the sidewalls of the channel layer 22 and the surface of the channel layer 22 far from the first intermediate layer 21.

In this embodiment, a material of the channel structure 2 includes a group-III nitride material. The materials of the first intermediate layer 21 and the second intermediate layer 23 can be dielectric materials, the materials of the first intermediate layer 21 and the second intermediate layer 23 include AlN, and the material of the channel layer 22 includes GaN, AlGaN, InGaN, or AlInGaN. The present disclosure does not limit the materials of the channel structure 2.

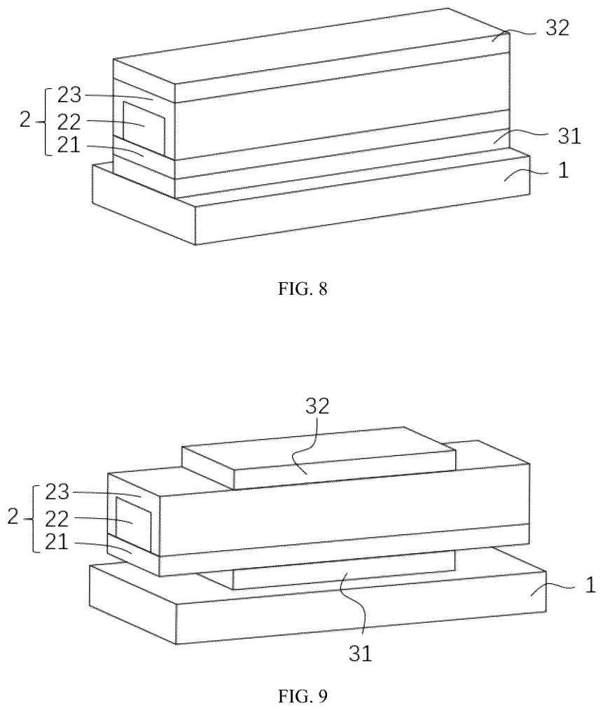

Referring to FIG. 8, the second N-type heavily doped layer 32 is manufactured on the channel structure 2. The second N-type heavily doped layer 32 is on the surface of the second intermediate layer 23 far from the substrate 1.

Refer to FIG. 9, the parts of the first N-type heavily doped layer 31 whose projection on the channel structure 2 is within the source region and the drain region are removed, and the parts of the second N-type heavily doped layer 32 whose projection on the channel structure 2 is within the source region and the drain region are removed.

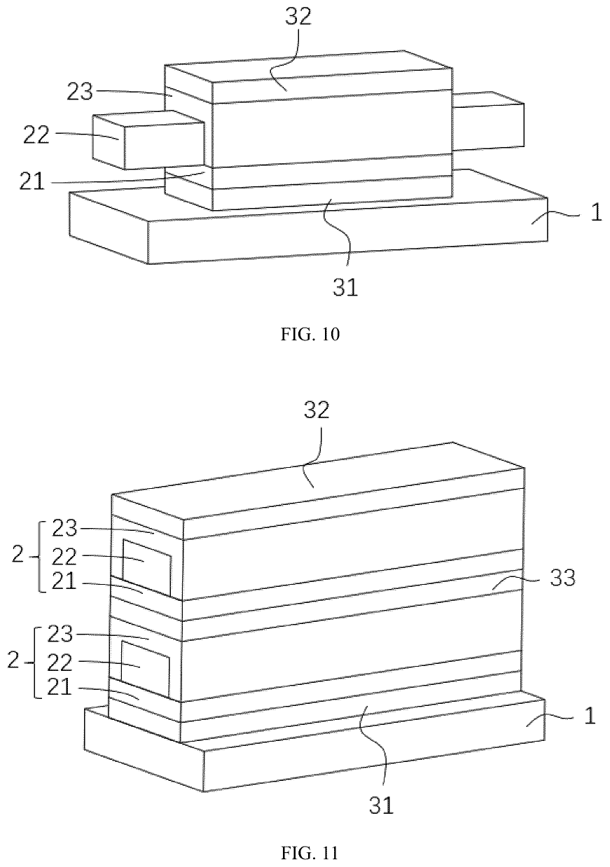

Referring to FIG. 10, after removing the parts of the first N-type heavily doped layer 31 whose projection on the channel structure 2 is within the source region and the drain region, and the parts of the second N-type heavily doped layer 32 whose projection on the channel structure 2 is within the source region and the drain region, the method further includes removing parts of the first intermediate layer 21 within the source region and the drain region, and parts of the second intermediate layer 23 within the source region and the drain region.

Further referring to FIG. 1, after removing parts of the first intermediate layer 21 within the source region and the drain region, and parts of the second intermediate layer 23 within the source region and the drain region, the method further includes manufacturing the source electrode 5 and the drain electrode 6 respectively in the source region and the drain region, where the source electrode 5 and the drain electrode 6 both wrap around the channel layer 22; and manufacturing the gate electrode 4 within the gate region, where the gate electrode 4 covers the sidewalls of the first N-type heavily doped layer 31, the channel structure 2, and the second N-type heavily doped layer 32, and in some embodiments, the gate electrode 4 can further cover the top of the second N-type heavily doped layer 32 far from the substrate 1. The gate electrode 4 is usually a metal material, such as nickel, nickel manganese alloy, etc., which is not limited in the present disclosure. In some embodiments, the gate electrode 4 forms ohmic contact with the first N-type heavily doped layer 31 and the second N-type heavily doped layer 32 to reduce Ohmic contact resistance and improve gate control capability.

The manufacturing of the gate electrode 4, the source electrode 5, and the drain electrode 6 may include electron beam evaporation, such as thermal evaporation, sputtering, etc., which is not limited in the present disclosure.

In some embodiments, before epitaxial growth of the first N-type heavily doped layer 31, a nucleation layer and a buffer layer can be sequentially grown on the side of the substrate 1 close to the first N-type heavily doped layer 31. A material of the nucleation layer can include, for example, AlN, AlGaN, etc., and a material of the buffer layer can include at least one of AlN, GaN, AlGaN or AlInGaN. The manufacturing of nucleation layer and buffer layer can be similar to the manufacturing of the first N-type heavily doped layer 31, the first intermediate layer 21, the channel layer 22, the second intermediate layer 23, and the second N-type heavily doped layer 32. The nucleation layer can alleviate the lattice mismatch and thermal mismatch between the epitaxial grown semiconductor layer and the substrate, while the buffer layer can reduce the dislocation density and defect density of the epitaxial grown semiconductor layer, which can improve crystal quality.

### Embodiment 4

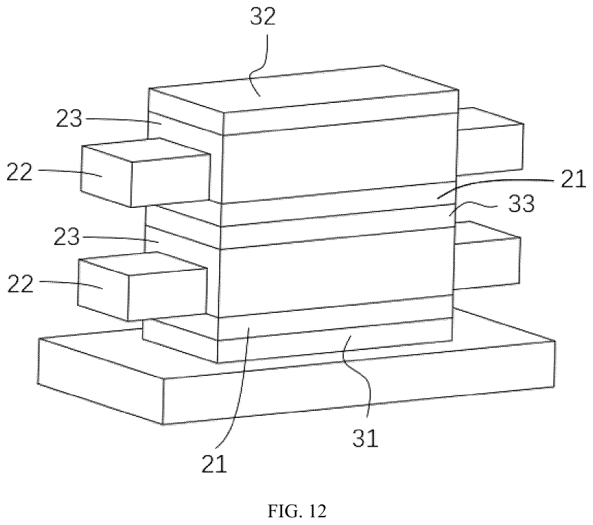

Embodiment 4 provides the manufacturing process of the semiconductor structure provided in Embodiment 2. The content of Embodiment 4 is roughly the same as that of Embodiment 3, with the only difference being that, as shown in FIGS. 11 to 12, schematic diagrams of a partial flow for manufacturing the semiconductor structure provided in Embodiment 4 of the present disclosure, combined with FIGS. 3 to 4, manufacturing the channel structure 2 includes manufacturing a plurality of the channel structures 2, the plurality of the channel structures 2 are stacked on the top of the first N-type heavily doped layer 31.

The manufacturing of the plurality of channel structures 2 is similar to the manufacturing of the first N-type heavily doped layer 31, the first intermediate layer 21, the channel layer 22, the second intermediate layer 23, and the second N-type heavily doped layer 32, and will not be repeated here.

In some embodiments, manufacturing the plurality of channel structures 2 further includes manufacturing at least one third N-type heavily doped layer 33, where each third N-type heavily doped layer 33 is between two adjacent channel structures 2 in the plurality of channel structures 2 (i.e., above the second intermediate layer 23 of the lower channel structure 2 and below the first intermediate layer 21 of the upper channel structure 2) The gate electrode 4 is connected to the third N-type heavily doped layer 33, and the gate electrode 4 is in ohmic contact with the third N-type heavily doped layer 33.

After manufacturing the plurality of channel structures 2, when removing the parts of the first N-type heavily doped layer 31 whose projection on the channel structure 2 is within the source region and the drain region, and the parts of the second N-type heavily doped layer 32 whose projection on the channel structure 2 is within the source region and the drain region, parts of the third N-type heavily doped layer 33 whose projection on the channel structure 2 is within the source and drain regions can also be removed.

The manufacturing of the third N-type heavily doped layer 33 is similar to the manufacturing of the first N-type heavily doped layer 31, the first intermediate layer 21, the channel layer 22, the second intermediate layer 23, and the second N-type heavily doped layer 32. The implementation of etching the parts of the third N-type heavily doped layer 33 whose projection on the channel structure 2 is within the source and drain regions is similar to the implementation of etching the parts of the first N-type heavily doped layer 31 whose projection on the channel structure 2 is within the source region and the drain region, and the parts of the second N-type heavily doped layer 32 whose projection on the channel structure 2 is within the source region and the drain region, and will not be repeated here.

The specific structure, principle, function, and effect in the embodiments of the manufacturing method are similar to those described in the embodiments of the semiconductor structure mentioned above. Reference can be made to the content described in the structural embodiments, which will not be repeated here.

It should be noted that, in the embodiments, a certain material is represented by chemical elements, but a molar ratio of each chemical element in the material is not limited. For example, GaN materials contain Ga clement and N element, but the molar proportions of Ga clement and N element are not limited; AlGaN materials contain three elements, Al, Ga and N, but their molar proportions are not limited.

The above describes the basic principles of the present disclosure in conjunction with specific embodiments. However, it should be pointed out that the advantages, superiority, effects, etc. mentioned in the present disclosure are only examples and not limitations, and cannot be considered as essential in various embodiments of the present disclosure. In addition, the specific details disclosed above are only for illustrative purposes and for case of understanding, and are not limitation. The above details do not limit the necessity for the present disclosure to be implemented using the aforementioned specific details.

The block diagrams of the devices, apparatuses, and systems involved in the present disclosure are only illustrative examples and are not intended to require or imply that they must be connected, arranged, or configured in the manner shown in the block diagrams. As those skilled in the art will recognize, these devices, apparatuses, and systems can be connected, arranged, and configured in any way. Words such as “include”, “comprise”, “have”, etc. are open-ended terms that refer to “include but not limited to” and can be used interchangeably with it. The terms “or” and “and” used here refer to the words “and/or” and can be used interchangeably with it, unless the context clearly indicates otherwise. The term “such as” used here refers to the phrase “such as but not limited to” and can be used interchangeably with it.

It should also be pointed out that in the apparatuses, devices, and methods of the present disclosure, each component or step can be decomposed and/or recombined. These decompositions and/or recombinations should be considered equivalent solutions of the present disclosure.

The above description of the disclosed aspects is provided to enable any person skilled in the art to make or use the present disclosure. The various modifications to these aspects are very obvious to those skilled in the art, and the general principles defined here can be applied to other aspects without departing from the scope of the present disclosure. Therefore, the present disclosure is not intended to be limited to the aspects shown herein, but rather to the widest range consistent with the principles and novel features disclosed herein.

For the purpose of illustration and description, the above description has been provided. Furthermore, this description is not intended to limit the embodiments of the present disclosure to the form disclosed herein. Although multiple exemplary aspects and embodiments have been discussed above, those skilled in the art will recognize certain variations, modifications, alterations, additions, and sub combinations thereof.

What is claimed is:

1. A semiconductor structure, comprising:
a substrate;
a channel structure on the substrate, wherein the channel structure comprises a first intermediate layer, a channel layer, and a second intermediate layer that are arranged on the substrate, wherein a width of a cross-section of the channel layer is smaller than a width of a cross-section of the first intermediate layer, and the second intermediate layer covers sidewalls of the channel layer and a surface of the channel layer far from the first intermediate layer, wherein the channel structure comprises a gate region, and a source region and a drain region at both sides of the gate region;
a first N-type heavily doped layer and a second N-type heavily doped layer, wherein the first N-type heavily doped layer is between the substrate and the channel structure, and the second N-type heavily doped layer is on a side of the channel structure far from the substrate, and projection of the first N-type heavily doped layer on the channel structure and projection of the second N-type heavily doped layer on the channel structure are located within the gate region; and
a gate electrode within the gate region, wherein the gate electrode covers sidewalls of the first N-type heavily doped layer, the channel structure, and the second N-type heavily doped layer.

2. The semiconductor structure according to claim 1, wherein the gate electrode is in ohmic contact with the first N-type heavily doped layer and the second N-type heavily doped layer.

3. The semiconductor structure according to claim 1, wherein the semiconductor structure comprises:
a plurality of the channel structures that are stacked on the substrate; and
a third N-type heavily doped layer between adjacent channel structures of the plurality of channel structures, wherein projection of the third N-type heavily doped layer on the channel structure is located within the gate region.

4. The semiconductor structure according to claim 3, wherein the plurality of channel structures share the gate electrode, the gate electrode covers sidewalls of the third N-type heavily doped layer, and the gate electrode is in ohmic contact with the third N-type heavily doped layer.

5. The semiconductor structure according to claim 4, wherein the plurality of channel structures share the gate electrode, a source electrode, and a drain electrode.

6. The semiconductor structure according to claim 1, wherein the channel layer is a nanowire structure or a nanosheet structure.

7. The semiconductor structure according to claim 1, wherein a material of the channel structure comprises a group-III nitride material.

8. The semiconductor structure according to claim 1, wherein materials of the first intermediate layer and the second intermediate layer comprises AlN; and a material of the channel layer comprises GaN, AlGaN, InGaN, or AlInGaN.

9. The semiconductor structure according to claim 1, wherein the channel layer is an N-type lightly doped layer, and doping concentration of N-type ions for the channel layer is less than 1E18.

10. The semiconductor structure according to claim 9, wherein a doping concentration of the first N-type heavily doped layer is greater than 1E18, and a doping concentration of the second N-type heavily doped layer is greater than 1E18.

11. The semiconductor structure according to claim 1, further comprising:
a source electrode and a drain electrode that are respectively at the source region and the drain region, wherein the source electrode and the drain electrode both wrap around the channel layer.

12. A manufacturing method for a semiconductor structure, comprising:
providing a substrate;
sequentially manufacturing a first N-type heavily doped layer, a channel structure, and a second N-type heavily doped layer on the substrate, wherein manufacturing the channel structure comprises sequentially manufacturing a first intermediate layer, a channel layer, and a second intermediate layer on the first N-type heavily doped layer, wherein a width of a cross-section of the channel layer is smaller than a width of a cross-section of the first intermediate layer, and the second intermediate layer covers sidewalls of the channel layer and a surface of the channel layer far from the first intermediate layer, wherein the channel structure comprises a gate region, and a source region and a drain region at both sides of the gate region;
removing parts of the first N-type heavily doped layer whose projection on the channel structure is within the source region and the drain region, and parts of the second N-type heavily doped layer whose projection on the channel structure is within the source region and the drain region; and
manufacturing a gate electrode within the gate region, wherein the gate electrode covers sidewalls of the first N-type heavily doped layer, the channel structure, and the second N-type heavily doped layer.

13. The manufacturing method according to claim 12, wherein manufacturing the channel structure comprises:
sequentially manufacturing the first intermediate layer and the channel layer on the first N-type heavily doped layer;
patterning the channel layer, to enable the width of the cross-section of the channel layer to be smaller than the width of the cross-section of the first intermediate layer; and
manufacturing the second intermediate layer on the first intermediate layer and the channel layer, wherein the second intermediate layer covers the sidewalls of the channel layer and the surface of the channel layer far from the first intermediate layer.

14. The manufacturing method according to claim 13, wherein patterning the channel layer comprises:
patterning the channel layer to form a nanowire structure or a nanosheet structure.

15. The manufacturing method according to claim 12, further comprising:
removing parts of the first intermediate layer that are located within the source region and the drain region, and parts of the second intermediate layer that are located within the source region and the drain region.

16. The manufacturing method according to claim 15, further comprising:
respectively manufacturing a source electrode and a drain electrode at the source region and the drain region, wherein the source electrode and the drain electrode both wrap around the channel layer.

17. The manufacturing method according to claim 12, wherein the gate electrode is in ohmic contact with the first N-type heavily doped layer and the second N-type heavily doped layer.

18. The manufacturing method according to claim 13, wherein manufacturing the channel structure comprises manufacturing a plurality of the channel structures that are stacked on the substrate; and the manufacturing method further comprises:
manufacturing a third N-type heavily doped layer between adjacent channel structures in the plurality of channel structures, wherein the gate electrode is connected to the third N-type heavily doped layer, and the gate electrode is in ohmic contact with the third N-type heavily doped layer.

19. The manufacturing method according to claim 18, wherein removing the parts of the first N-type heavily doped layer whose projection on the channel structure is within the source region and the drain region, and the parts of the second N-type heavily doped layer whose projection on the channel structure is within the source region and the drain region comprises:
removing the parts of the first N-type heavily doped layer whose projection on the channel structure is within the source region and the drain region, the parts of the second N-type heavily doped layer whose projection on the channel structure is within the source region and the drain region, and parts of the third N-type heavily doped layer whose projection on the channel structure is within the source region and the drain region.

20. The manufacturing method according to claim 12, further comprising:
performing N-type doping on the channel layer, wherein doping concentration of N-type ions is less than 1E18.
